(19) United States
(12) Patent Application Publication
(10) Pub. No.: US 2013/0239832 A1
(43) Pub. Date: Sep. 19, 2013

(54) POSITIVE-WORKING LITHOGRAPHIC PRINTING PLATE PRECURSORS

(71) Applicants: Celin Savariar-Hauck, Badenhausen (DE); Gerhard Hauck, Badenhausen (DE); Andrea Pauls, Osterode (DE)

(72) Inventors: Celin Savariar-Hauck, Badenhausen (DE); Gerhard Hauck, Badenhausen (DE); Andrea Pauls, Osterode (DE)

(21) Appl. No.: 13/421,951

(22) Filed: Mar. 16, 2012

(51) Int. Cl. B41N 1/08; G03F 7/20; G03F 7/075

(52) U.S. Cl. 101/453; 430/281.1; 430/302

(57) ABSTRACT

Infrared radiation-sensitive, positive-working lithographic printing plate precursors have improved scratch resistance in their outermost imageable layer because that layer comprises a unique combination of first and second alkali solution-soluble or -dispersible resins. The first alkali solution-soluble or -dispersible resin is an acid-functionalized novolak or acid-functionalized resole resin. The second alkali solution-soluble or -dispersible resin is a polyurethane or polyurethane urea comprising a polysiloxane unit segment in the polyurethane or polyurethane urea backbone or a side chain.

### FIELD OF THE INVENTION

This invention relates to single- and multi-layer positive working lithographic printing plate precursors that exhibit improved scratch resistance because of a unique polymer formulation in the outermost layer. This invention also relates to methods of preparing lithographic printing plates from these lithographic printing plate precursors.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Lithographic printing plate precursors useful to prepare lithographic printing plates typically comprise one or more imageable layers applied over the hydrophilic surface of a substrate. The imageable layers include one or more radiation-sensitive components that can be dispersed in a suitable binder. Alternatively, the radiation-sensitive component can also be the binder material. Following imaging, either the imaged regions or the non-imaged regions of the imageable layer are removed using a suitable developer or processing solution, revealing the underlying hydrophilic surface of the substrate. If the imaged regions are removed, the precursor is considered as positive-working. Conversely, if the non-imaged regions are removed, the precursor is considered as negative-working. In each instance, the regions of the imageable layer (that is, the image areas) that remain are ink-receptive, and the regions of the hydrophilic surface revealed by the developing process accept water and aqueous solutions, typically a fountain solution, and repel ink.

Direct digital or thermal imaging has become increasingly important in the printing industry because of their stability to ambient light. The precursors for the preparation of lithographic printing plates have been designed to be sensitive to heat or infrared radiation and can be exposed using thermal heads of more usually, infrared laser diodes that image in response to signals from a digital copy of the image in a computer a platesetter.

Particulate materials have been incorporated into lithographic printing plate precursors for various reasons. For example, organic polymer particles have been incorporated into such precursors for improved press developability as described in U.S. Pat. No. 6,352,811 (Patel et al.). Nanopastes of metallic particles are described for lithographic printing plate precursors in U.S. Pat. No. 7,217,502 (Ray et al.). Core-shell particles have been included in imaging layers so they coalesce upon imaging as described for example in EP 1,057,622 (Fukino et al.). WO 2009/032080 (Hauck et al.) describes the use of nanoparticles to improve scratch resistance. WO 2009/114056 (Hauck et al.) also describes means for improving scratch resistance as well as reducing tackiness.

Positive-working lithographic printing plate precursors are generally very sensitive to scratches in the outer surface. Special handling and packaging operations are required to minimize damage. For example, lithographic printing plate precursors are generally packaged and shipped after manufacture in multiple units or stacks with interleaving paper between individual elements. During manufacturing, packaging, transport, and subsequent use of the imageable elements, the outermost layers can be scratched or abraded from human or machine handling. Such damage can produce “holes” or other defects in the resulting images, which obviously is a major problem.

This problem has been addressed as described in U.S. Patent Application Publication 2009/0061352 (Hauck et al.) by incorporating non-metallic, inert discrete particles in the outermost imageable layer. These discrete particles have an average particle size of from about 1 nm to about 0.5 μm, and can be present in the outermost imageable layer in an amount of at least 1% based on total outermost imageable layer dry weight.

EP 1,747,899A1 (Hauck et al.) describes positive-working lithographic printing plate precursors having an outermost imageable layer that comprises a polysiloxane having a glass transition temperature of more than 60° C. and a hydroxyl content of at least 1 weight %.

Despite these advances in the art, there continues to be a need to improve the scratch resistance of the outermost imageable layers in positive-working lithographic printing plate precursors.

### SUMMARY OF THE INVENTION

The present invention addresses this scratch problem and provides a positive-working lithographic printing plate precursor that comprises:

a substrate,

an outermost imageable layer that is disposed over the substrate, and that comprises a combination of first and second alkali solution-soluble or -dispersible resins,

the positive-working lithographic printing plate precursor further comprising an infrared radiation absorber in the outermost imageable layer or in a different layer underneath the outermost imageable layer,

wherein the first alkali solution-soluble or -dispersible resin is a acid-functionalized novolak or acid-functionalized resole resin, and

wherein the second alkali solution-soluble or -dispersible resin is a polyurethane or polyurethane urea comprising a polysiloxane unit segment in the polyurethane or polyurethane urea backbone or side chain.

This invention also provides particularly useful embodiments in which the lithographic printing plate precursor further comprises an inner imageable layer disposed over the substrate and under the outermost imageable layer, and wherein:

the substrate is an aluminum-containing substrate,

the inner imageable layer comprises an infrared radiation absorber and at least one alkali solution-soluble or -dispersible polymeric binder that is different than the first and second alkali solution-soluble or -dispersible resins, and

the outermost imageable layer comprises a combination of a first alkali solution-soluble or -dispersible resin and a second alkali solution-soluble or -dispersible resin,

wherein:

(a) the second alkali solution-soluble or -dispersible resin is a polyurethane or polyurethane urea that is derived from:
(i) reacting at least one polyisocyanate with a compound comprising two or more functional groups selected from the group consisting of hydroxyl and amino groups having at least one active hydrogen atom attached to the amino nitrogen atom, wherein the polyisocyanate is functionalized with a polysiloxane segment, either in its main chain or a side chain, or
(ii) reacting at least one polyisocyanate with a compound comprising two or more functional groups selected from the group consisting of hydroxyl and amino groups having at least one active hydrogen atom attached to the amino nitrogen atom, wherein the compound also comprises polysiloxane segments either in its main chain or a side chain,

(b) the first alkali solution-soluble or -dispersible resin is present in the outermost imageable layer in an amount of at least 10 weight % and up to and including 90 weight % based on the outermost imageable layer total dry weight,

(c) the second alkali solution-soluble or -dispersible resin is present in the outermost imageable layer in an amount of at least 5 weight % and up to and including 75 weight % based on the outermost imageable layer total dry weight, and

(d) the weight ratio of the first alkali solution-soluble or -dispersible resin to the second alkali solution-soluble or -dispersible resin is from 0.2:1 and to and including 5:1.

This invention further provides a method for forming a lithographic printing plate, comprising:

imagewise exposing the positive-working lithographic printing plate precursor of this invention (for example, as described above in this Summary) with infrared radiation to form an imaged precursor comprising exposed regions and non-exposed regions in the outermost imageable layer, and

processing the imaged precursor to remove the exposed regions of the outermost imageable layer.

In addition, the method of this invention can be used to make a lithographic printing plate comprising an aluminum substrate having thereon an outermost imageable layer having non-exposed regions,

which non-exposed regions comprise a combination of first and second alkali solution-soluble or -dispersible resins,

wherein the first alkali solution-soluble or -dispersible resin is a acid-functionalized novolak or acid-functionalized resole resin, and

wherein the second alkali solution-soluble or -dispersible resin is a polyurethane or polyurethane urea comprising a polysiloxane unit segment in the polyurethane or polyurethane urea backbone or side chain,

the lithographic printing plate further comprising an infrared radiation absorber in the non-exposed regions of the outermost imageable layer or in a different layer underneath the non-exposed regions of the outermost imageable layer.

The lithographic printing plate precursors of this invention exhibit improved scratch resistance in the outermost imageable layer because of the use of a unique combination of first and second alkali solution-soluble or alkali solution-dispersible resins that are defined in more detail below. The use of each of these types of resins alone fails to provide this improvement. In addition, it was found that by incorporating a polysiloxane unit segment within the second alkali solution-soluble or -dispersible resin, any adverse interaction of novolak resins with siloxane is minimized It was also found that precursors containing these outermost imageable layers can be readily developed in alkali solutions (developers or processing solutions) having relatively lower pH than is normally used. For example, processing solutions having a pH of at least 7 and up to and including 12 can be used in the present invention, as well as silicate-free processing solutions.

### DETAILED DESCRIPTION OF THE INVENTION

### Definitions

As used herein to define various components of the laser-engraveable compositions, formulations, and layers, unless otherwise indicated, the singular forms “a”, “an”, and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term's definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

Unless otherwise indicated, percentages refer to percents by dry weight of a composition or layer, or % solids of a solution.

As used herein, the term “radiation absorber” refers to compounds that are sensitive to certain wavelengths of radiation and can convert photons into heat within the layer in which they are disposed. For example, “infrared radiation absorbers” refer to compounds that are sensitive to radiation as described below.

As used herein, the term “infrared” refers to radiation having a λₘₐₓ of at least 700 nm and higher. In most instances, the term “infrared” is used to refer to the “near-infrared” region of the electromagnetic spectrum that is defined herein to be at least 700 nm and up to and including 1400 nm.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the terms “polymer” and “polymeric” refer to high and low molecular weight polymers including oligomers and includes homopolymers and copolymers.

The term “copolymer” refers to polymers that are derived from two or more different monomers, in random order along the polymer backbone. That is, they comprise recurring units having different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Positive-Working Lithographic Printing Plate Precursors

The lithographic printing plate precursors of the present invention are positive-working and include one or more imageable layers disposed on a suitable substrate.

Some embodiments of these positive-working lithographic printing plate precursors comprise a single outermost imageable layer disposed over the substrate while other embodiments comprise an inner layer disposed over the substrate and an outermost imageable layer disposed over the inner layer.

The substrate generally has a hydrophilic surface, or at least a surface that is more hydrophilic than the applied imageable layer(s) on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports can be modified on one or both flat surfaces with a “subbing” layer to enhance hydrophilicity, or paper supports can be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

One useful substrate is composed of an aluminum support that can be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of at least 1.5 and up to and including 5 g/m² and more typically at least 3 and up to and including 4.3 g/m². Phosphoric acid anodization generally provides an oxide weight on the surface of from at least 1.5 and up to and including 5 g/m² and more typically at least 1 and up to and including 3 g/m². When sulfuric acid is used for anodization, higher oxide weight (at least 3 g/m²) can provide longer press life.

An interlayer can be formed by treatment of the aluminum support with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support can be treated with a phosphate solution that can further contain an inorganic fluoride (PF). The aluminum support can be electrochemically-grained, sulfuric acid-anodized, and treated with PVPA or PF using known procedures to improve surface hydrophilicity.

A substrate an also comprise a grained and sulfuric acid anodized aluminum-containing support that has also been treated with an alkaline or acidic pore-widening solution to provide its outer surface with columnar pores so that the diameter of the columnar pores at their outermost surface is at least 90% of the average diameter of the columnar pores. This substrate further comprises a hydrophilic layer disposed directly on the grained, sulfuric acid anodized and treated aluminum-containing support, and the hydrophilic layer comprises a non-crosslinked hydrophilic polymer having carboxylic acid side chains. Further details of such substrates and methods for providing them are provided in copending and commonly assigned U.S. Ser. No. 13/221,936 (filed Aug. 31, 2011 by Hayashi) that is incorporated herein by reference.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate can be coated with antistatic agents or slipping layers or a matte layer to improve handling and “feel” of the imageable element.

Some embodiments of this invention include a single imageable layer that is also the outermost imageable layer in the lithographic printing plate precursor. In such embodiments, the outermost imageable layer comprises the unique combination of first and second alkali solution-soluble or alkali solution-dispersible resins described below (also known below as “first” and “second” resins) that provides the advantages of the present invention. In most embodiments, each of these first and second alkali solution-soluble or -dispersible resins are also water-insoluble, meaning that after 48 hours at room temperature, at least 50 weight % of a resin sample does not dissolve in water.

In the outermost imageable layer, the first alkali solution-soluble or -dispersible resin can be an acid-functionalized novolak or acid-functionalized resole resin. Mixtures of either type of resin or mixture of both types of resins can be used if desired. Non-functionalized novolaks and resoles are well known in the art and they can be readily functionalized with carboxy, sulfo, or phospho groups using known procedures. For example, the phenolic groups in novolaks and resoles can be etherified with chloro acetic acid to provide functional carboxyl groups. More details of such functionalized resins are provided for example, in U.S. Pat. No. 7,582,407 (Savariar-Hauck et al.) that is incorporated herein by reference, and this patent describes some useful functionalized novolaks and resoles. The functional acidic groups can be pendant from the resin backbone, or they can be incorporated as part of the resin backbone.

Particularly, useful first alkali solution-soluble or -dispersible resins are carboxy-functionalized novolaks and carboxy-functionalized resoles.

Generally, such first alkali solution-soluble or -dispersible resins have a number average molecular weight of at least 3,000 and up to and including 200,000, and typically at least 6,000 and up to and including 100,000, as determined using gel permeation chromatography (GPC) with polystyrene standards.

Typical novolak resins that can be functionalized include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or an m,p-cresol mixture with formaldehyde using conventional conditions. For example, some useful novolak resins that can be functionalized include but are not limited to, xylenol-cresol resins, for example, SPN400, SPN420, SPN460, SPN562 and VPN1100 (that are available from AZ Electronics) and EP25D40G and EP25D50G.

The first alkali solution-soluble or -dispersible resin is generally present in the outermost imageable layer in an amount of at least 10 weight % and up to and including 90 weight %, and typically of at least 30 weight % and up to and including 80 weight %, all based on the outermost imageable layer total dry weight.

The outermost imageable layer also comprises a second alkali solution-soluble or -dispersible resin that comprises a polysiloxane unit segment in a polyurethane or polyurethane urea backbone or side chain. The polysiloxane unit segments can be introduced into the resins by reacting at least one polyisocyanate with a compound having mono- or difunctional terminal hydroxy or amine groups. Thus, the polysiloxane can be reacted with siloxane diols or diamines in a polyaddition reaction. Alternatively, they can be introduced by using siloxane functionalized isocyanates, or anhydrides can be used to introduce the polysiloxane unit segments into polyurethane chains. Introduction of the polysiloxane unit segments thus can be accomplished by either copolymerization or grafting procedures (grafting the polysiloxane unit segments to a main polymer chain using acetalization) that are known in the art and such introduction of the desired moieties would be readily apparent to a skilled worker in view of the teaching in this disclosure.

The term “polyisocyanate” refers to a compound that comprises two or more isocyanate groups. In most embodiments, the polyisocyanate is a diisocyanate comprising two isocyanate groups.

In many embodiments, the second alkali solution-soluble or -dispersible resin is a polyurethane or polyurethane urea that is derived from:

(i) reacting at least one polyisocyanate with a compound comprising difunctional terminal hydroxyl or amine groups, wherein the polyisocyanate is functionalized with a polysiloxane segment, either in its main chain or a side chain, or

(ii) reacting at least one polyisocyanate with a compound comprising mono- or difunctional terminal hydroxyl or amine groups, wherein the compound also comprises polysiloxane segments either in its main chain or a side chain.

Mixtures of the each type of resin, or mixtures of both types of resins can be used in the practice of this invention.

The polyurethane urea can also comprise a unit having a substituent having an acidic hydrogen atom. For example, the substituent having an acidic hydrogen atom can be selected from the group consisting of a carboxy group, —SO₂NHCOO— group, —CONHSO₂— group, —CONHSO₂NH— group, and —NHCONHSO₂— group. A carboxy group is particularly useful. Multiple different substituents can be present in the same molecule.

The polysiloxane moiety can have a linear, a partially branched, branched, or cyclic structure, and a linear structure is particularly useful. The linear polysiloxane moiety can be R₃SiO—(R₂SiO)ᵢ—R₂Si—, R₃SiO—(R₂SiO)ⱼ—R₂SiO—and similar groups that would be readily apparent to a skilled worker, wherein the R groups independently represent a C₁₋₂₀ alkyl group, a C₆₋₂₀ aryl group, or a C₇₋₂₀ aralkyl group (aryl-substituted alkyl groups); and i and j are independently integers of from 1 to and including 10,000. The C₁₋₂₀ alkyl groups include but are not limited to, substituted or unsubstituted linear or branched alkyl groups such as a methyl, ethyl, n-propyl, iso-butyl, pentyl, hexyl, heptyl, and octyl groups, and cycloalkyl groups such as substituted or unsubstituted cyclopentyl and cyclohexyl groups. Also included are C₁₋₂₀ alkyl groups in which one or more hydrogen atoms bonded to the carbon atom(s) are at least partially replaced with halogen atom(s) such as fluorine atom(s) or organic group(s) such as hydroxy, epoxy, glycidyl, acyl, carboxyl, amino, methacryl, and mercapto groups.

Useful C₆₋₂₀ aryl groups include but are not limited to substituted or unsubstituted phenyl, tolyl, xylyl, and mesityl groups and C₆₋₂₀ aryl groups in which one or more hydrogen atoms bonded to the carbon atom(s) thereof are at least partially replaced with halogen atom(s) such as fluorine atom(s) or organic groups such as hydroxy, epoxy, glycidyl, acyl, carboxyl, amino, methacryl, and mercapto groups. Useful C₇₋₂₀ aralkyl group include but are not limited to, substituted or unsubstituted benzyl and phenethyl groups as well as C₇₋₂₀ aralkyl groups in which one or more hydrogen atoms bonded to the carbon atom(s) thereof are at least partially replaced with halogen atom(s) such as fluorine atom(s) or organic group(s) such as hydroxy, epoxy, glycidyl, acyl, carboxyl, amino, methacryl group, and mercapto groups.

The second alkali solution-soluble or -dispersible resin is a polyurethane or polyurethane urea that is derived from:

(i) reacting at least one polyisocyanate with a compound comprising two or more functional groups selected from the group consisting of hydroxyl and amino groups having at least one active hydrogen atom attached to the amino nitrogen atom, wherein the polyisocyanate is functionalized with a polysiloxane segment, either in its main chain or a side chain, or

(ii) reacting at least one polyisocyanate with a compound comprising two or more functional groups selected from the group consisting of hydroxyl and amino groups having at least one active hydrogen atom attached to the amino nitrogen atom, wherein the compound also comprises polysiloxane segments either in its main chain or a side chain.

For example, the polyurethane comprising a polysiloxane segment in the backbone or a side chain can be obtained from the reaction of (a) at least one diisocyanate component, and (b) a diol component that comprises a polysiloxane moiety and optionally a substituent having an acidic hydrogen atom.

The polyurethane urea comprising a polysiloxane moiety in the backbone or a side chain, can be obtained from the reaction of (a) at least one diisocyanate component, (b) a diol component comprising either a diol comprising a polysiloxane moiety in the backbone or side chain, and optionally a substituent having an acidic hydrogen atom, or a diol comprising a polysiloxane moiety in both the backbone and a side chain, and (c) at least one diamine component.

The molar ratio of the diisocyanate component to (the diol component (or the diol component with the diamine component) is generally at least 0.7:1 to and including 1.5:1. When an isocyanate group remains at the end of the polymer, it is possible to synthesize the resin by treating with alcohols or amines so that an isocyanate group does not finally remain.

The diisocyanate component is not limited as long as it comprises two isocyanate groups. Examples of the diisocyanate component include but are not limited to, 4,4′-diphenylmethane diisocyanate, xylylene diisocyanate, naphthylene-1,5-diisocyanate, tetramethylxylene diisocyanate, hexamethylene diisocyanate, toluene-2,4-diisocyanate, toluene-2,6-diisocyanate, isophorone diisocyanate, hydrogenated xylylene diisocyanate, dicyclohexylmethane diisocyanate, norbornene diisocyanate and trimethylhexamethylene diisocyanate, and dimer acid diisocyanate. Mixtures of these compounds can also be used.

The diol comprising a substituent having an acidic hydrogen atom is not limited but can have a group selected from the group consisting of a carboxy group, —SO₂NHCOO— group, —CONHSO₂— group, —CONHSO₂NH— group, and —NHCONHSO₂— group, with the carboxy group being particularly useful.

Diols having a carboxy group include but are not limited to, 3,5-dihydroxybenzoic acid, 2,2-bis(hydroxymethyl)propionic acid, 2,2-bis(hydroxyethyl)propionic acid, 2,2-bis(3-hydroxypropylpropionic acid, 2,2-bis(hydroxymethyl)acetic acid, bis-(4-hydroxyphenyl)acetic acid, 4,4-bis-(4-hydroxyphenyl)pentanoic acid and tartaric acid. 2,2-Bis(hydroxymethyl)-propionic acid is particularly useful for its reactivity with an isocyanate.

The amount of the diol comprising a substituent having an acidic hydrogen atom is generally at least 50 weight % and up to and including 95% weight %, or typically at least 55 weight % and up to and including 90 weight %, relative to the total weight of the diol component.

The diol having a polysiloxane moiety in the backbone or a side chain is not limited as long as it has the noted polysiloxane moiety. It is particularly useful that it has no silicon atom-bonded hydroxy group.

In some embodiments, the compound in (ii) noted above is a diol that is used to prepare the second alkali solution-soluble or -dispersible resin that has a polysiloxane segment in the backbone or a side chain, and is a hydroxy-modified di-oliganosiloxane having both terminal groups represented by the following structure:

—(CₖH₂ₖ)ₚ—(OCₘH₂ₘ)_{q}—(OCₙH₂ₙ)ᵣ—(C₆H₄)ₛ—OH

wherein k, m, and n independently represent integers of from 1 to and including 3,

p represents an integer of 1 or more,

q represents 0 or an integer of from 1 to and including 100,

r represents 0 or an integer of from 1 to and including 100, and

s represents 0 or an integer of from 1 to and including 3.

In many embodiments, p represents an integer of from 1 to and including 3 (or typically 1 or 2), q represents 0 or an integer of from 1 to and including 50 (or typically 0 or 1 to and including 30), r represents 0 or an integer of from 1 to and including 50 (or typically 0 or 1 to and including 30), and s represents 0, 1, or 2 (or typically 0 or 1).

Useful terminal hydroxy-modified diorganopolysiloxanes can be obtained from a number of commercial sources, including for example the products sold by Shin Etsu Chemical Co., Ltd. as X-22-160AS, KF-6001, KF-6002, KF-6003, X-22-4272, X-22-4952, X-22-6266, X-22-1821 and X-22-1824B.

In other embodiments, the compound in (ii) noted above is a diol that is used to prepare a second alkali solution-soluble or -dispersible resin, and has a polysiloxane segment in its backbone or a side chain, which polysiloxane segment is a diol-modified di-organopolysiloxane that is represented by the following structure:

(R¹)₃SiO—[(R¹)₂SiO]ₜ—Si(R¹)₂R²

wherein the multiple R¹ groups independently represent a substituted or unsubstituted alkyl group (having 1 to 20 carbon atoms including substituted alkyl groups such as aralkyl groups) or a substituted or unsubstituted aryl group (having 6 to 20 total carbon atoms including the carbon atoms in the aromatic ring, such as substituted or unsubstituted phenyl or naphthyl groups including alkyl substituted phenyl or naphthyl groups).

R² represents the following structure:

—(CₖH₂ₖ)ᵤ—(OCₘH₂ₘ)ᵥ—(OCₙH₂ₙ)_{w}—(C₆H₄)ₓ—CR¹(R³)₂

wherein k, m, and n independently represent integers of from 1 to and including 3,

u represents an integer or 1 or more,

v represents 0 or an integer of from 1 to and including 100,

w represents 0 or an integer of from 1 to and including 100, and

x represents 0 or an integer of from 1 to and including 3,

R³ represents —(C_{y}H_{2y})_{z}OH wherein y represents an integer of from 1 to and including 3 and z represents an integer of from 1 to and including 100, and

t represents an integer of from 1 to and including 10,000.

In some embodiments of R², u represent an integer of from 1 to and including 3 (typically 1 or 2), v represents 0 or an integer of from 1 to 50 (typically 0 or an integer of from 1 to and including 30), w represents 0 or an integer of from 1 to 50 (typically 0 or an integer of from 1 to and including 30), x represents 0 or 2 (typically 0), y represents 1 or 2, z represents an integer of from 1 to and including 30 (typically 1 or 2), and t represents at least 100 and up to and including 10,000. The sum of v and w can be 1 in some embodiments.

Useful terminal hydroxy-modified diorganopolysiloxanes can be obtained from various commercial sources including Shin Etsu Chemical Co., Ltd. such as products X-22-176DX and X-22-176F.

The second alkali solution-soluble or -dispersible resins useful in the present invention can be prepared by known reaction procedures. For example, some useful reactants and resulting second alkali solution-soluble or -dispersible resins are described in TABLE I below for use in the Examples.

The second alkali solution-soluble or -dispersible resin is generally present in the outermost imageable layer in an amount of at least 5 weight % and up to and including 75 weight %, and typically of at least 15 weight % and up to and including 40 weight %, all based on the outermost imageable layer total dry weight.

Further, the weight ratio of the first alkali solution-soluble or -dispersible resin to the second alkali solution-soluble or -dispersible resin is from 0.2:1 and to and including 5:1 or more typically from 1:1 and to and including 2.5:1.

The lithographic printing plate precursor generally also comprises one or more infrared radiation absorbers. Such materials are sensitive to near-infrared or infrared radiation, for example of at least 700 and up to and including 1400 nm and typically at least 700 and up to and including 1200 nm.

Useful infrared radiation absorbers include but are not limited to, azo dyes, squarilium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,135,271 (Kawaushi et al.), and EP 1,182,033A2 (noted above) all of which are incorporated herein by reference.

Infrared radiation absorbing N-alkylsulfate cyanine dyes are described for example in U.S. Pat. No. 7,018,775 (Tao) that is incorporated herein by reference. A general description of one class of suitable cyanine dyes is shown by the formula in paragraph [0026] of WO 2004/101280 (Munnelly et al.) that is incorporated herein by reference.

Useful infrared radiation absorbing dyes are also described in U.S. Pat. No. 7,914,966 (Savariar-Hauck et al.), U.S. Pat. No. 7,955,779 (Levanon et al.), U.S. Pat. No. 8,034,538 (Strehmel et al.), U.S. Pat. No. 8,034,782 (Hauck et al.), and U.S. Pat. No. 8,119,331 (Baumann et al.), all of which are incorporated herein by reference.

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (noted above), U.S. Pat. No. 6,264,920 (Achilefu et al.), U.S. Pat. No. 6,153,356 (noted above), and U.S. Pat. No. 5,496,903 (Watanabe et al.) all of which are incorporated herein by reference. Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer) that is incorporated herein by reference.

The infrared radiation absorbers can be present in the lithographic printing plate precursor in an amount generally of at least 0.5 weight % and up to and including 30 weight % and typically at least 1 weight % and up to and including 10 weight %, based on total solids in a desired layer. The particular amount needed for this purpose would be readily apparent to a skilled worker in the art.

While in many embodiments, the infrared radiation absorber is present in the outermost imageable layer when there is only one imageable layer in the precursor, it can alternatively or additionally, be located in a different layer that is in thermal contact with and underneath the outermost imageable layer. In most of these embodiments, the different layer containing an infrared radiation absorber is directly (in contact with) the outermost imageable layer.

Other materials can be present in the outermost imageable layer including but not limited to, contrast dyes, coating surfactants, dispersing aids, humectants, biocides, viscosity builders, drying agents, defoamers, preservatives, and antioxidants. Such materials can be incorporated in amounts that would be readily apparent to a skilled worker in the art. For example, the following publications describe optional components for the outermost imageable layer useful in positive-working lithographic printing plate precursors: EP 1,543,046 (Timpe et al.), WO 2004/081662 (Memetea et al.), U.S. Pat. No. 6,255,033 (Levanon et al.), U.S. Pat. No. 6,280,899 (Hoare et al.), U.S. Pat. No. 6,391,524 (Yates et al.), U.S. Pat. No. 6,485,890 (Hoare et al.), U.S. Pat. No. 6,558,869 (Hearson et al.), U.S. Pat. No. 6,706,466 (Parsons et al.), U.S. Pat. No. 6,541,181 (Levanon et al.), U.S. Pat. No. 7,223,506 (Kitson et al.), U.S. Pat. No. 7,247,418 (Saraiya et al.), U.S. Pat. No. 7,270,930 (Hauck et al.), U.S. Pat. No. 7,279,263 (Goodin), and U.S. Pat. No. 7,399,576 (Levanon), EP 1,627,732 (Hatanaka et al.), and U.S. Published Patent Applications 2005/0214677 (Nagashima), 2004/0013965 (Memetea et al.), 2005/0003296 (Memetea et al.), and 2005/0214678 (Nagashima) all of which are incorporated herein by reference.

The outermost imageable layer can further comprise one or more developability enhancing compounds. A “developability-enhancing compound” is an organic compound that, when added to a positive-working radiation-sensitive imageable layer composition, reduces the minimum exposure energy required to completely remove the radiation-sensitive imageable layer in the exposed regions, in a suitable developer selected for that imageable layer, relative to the minimum exposure energy required to completely remove the same radiation-sensitive imageable layer in the exposed regions except for the exclusion of the organic compound. This difference will depend up on the particular organic compound and imageable layer composition used. In addition, such organic compounds can also be characterized as not substantially absorbing exposing radiation selected for the particular radiation-sensitive imageable layer, and generally have a molecular weight of less than 1000 g/mol.

Acidic Developability-Enhancing Compounds (ADEC), such as carboxylic acids or cyclic acid anhydrides, sulfonic acids, sulfinic acids, alkylsulfuric acids, phosphonic acids, phosphinic acids, phosphonic acid esters, phenols, sulfonamides, or sulfonimides can permit further improved developing latitude and printing durability. Representative examples of such compounds are provided in [0030] to [0036] of U.S. Patent Application Publication 2005/0214677 (Levanon et al.) that is incorporated herein by reference with respect to these acid developability-enhancing compounds.

The outermost imageable layer can also include a developability-enhancing composition containing one or more developability-enhancing compounds (DEC) as described in U.S. Patent Publication No. 2009/0162783 that is also incorporated herein by reference. Still other useful developability-enhancing compounds are also described in this publication using the following Structure (DEC₁):

[HO—C(═O)]ₘ-B-A-[N(R₄)(R₅)]ₙ (DEC₁)

wherein R₄ and R₅ in Structure DEC₁ are independently hydrogen or substituted or unsubstituted alkyl groups, substituted or unsubstituted cycloalkyl groups, or substituted or unsubstituted aryl groups, A is an organic linking group that comprises a substituted or unsubstituted phenylene directly attached to —[N(R₄)(R₅)]ₙ, B is a single bond or an organic linking group having at least one carbon, oxygen, sulfur, or nitrogen atom in the chain, m is an integer of 1 or 2, n is an integer of 1 or 2. The “B” organic linking group can be defined the same as A is defined above except that it is not required that B contain an arylene group, and usually B, if present, is different than A.

The one or more developability enhancing compounds described above are generally present in the outermost imageable layer in an amount of at least 1 weight % and up to and including 30 weight %, or typically at least 2 weight % and up to and including 20 weight %.

The single-layer lithographic printing plate precursor can be prepared by applying an outermost imageable layer formulation to a suitable substrate (including any hydrophilic layers on an aluminum sheet or cylinder) using conventional coating or lamination methods. Thus, the formulation can be formed by dispersing or dissolving the desired ingredients in a suitable coating solvent(s), and the resulting formulation can be applied to a substrate using suitable equipment and procedures, such as spin coating, knife coating, gravure coating, die coating, slot coating, bar coating, wire rod coating, roller coating, or extrusion hopper coating. The formulations can also be applied by spraying onto a suitable substrate.

The coating weight for the outermost imageable layer can be at least 0.5 g/m² and up to and including 3.5 g/m² and typically at least 1 g/m² and up to and including 2 g/m².

The selection of solvents used to coat the outermost imageable layer formulation depends upon the nature of the combined polymeric materials and other components incorporated therein. Generally, the formulation is coated out of acetone, methyl ethyl ketone, or another ketone, tetrahydrofuran, 1-methoxypropan-2-ol, 1-methoxy-2-propyl acetate, and mixtures thereof using conditions and techniques well known in the art. The coated layer can be dried in a suitable manner.

Other positive-working lithographic printing plate precursors of this invention are multi-layer imageable elements that comprise a suitable substrate, an inner layer (also known in the art as an “underlayer” or “innermost imageable layer”) disposed over the substrate, and an outermost imageable layer (also known in the art as a “outer layer”) disposed over the inner layer. Before thermal imaging, the outermost imageable layer is generally not soluble or removable by an alkaline developer within the usual time allotted for development, but after thermal imaging, the exposed regions of the outermost imageable layer are soluble or dispersible in an alkali solution (for example, developer). The inner imageable layer is also generally removable by the alkali solution (for example, developer).

In many embodiments, the outermost imageable layer is disposed directly on the inner imageable layer that is disposed directly on the substrate.

An infrared radiation absorber (described above) is also present in such imageable elements, and is typically present in the inner imageable layer but can optionally be in a separate layer between the inner imageable layer and the outermost imageable layer. In some embodiments, such infrared radiation absorbers are located only in the inner imageable layer.

These multi-layer lithographic printing plate precursors are formed by suitable application of an inner layer formulation onto a suitable substrate (described above).

The inner imageable layer is disposed between the outermost imageable layer and the substrate. Typically, it is disposed directly on the substrate (including any hydrophilic coatings as described above). The inner imageable layer comprises one or more polymeric binders that are removable by a suitable alkali solution processing solution. In addition, the one or more polymeric binders are usually insoluble in the solvent(s) used to coat the outermost imageable layer so that the outermost imageable layer can be coated over the inner imageable layer without dissolving the inner imageable layer. Mixtures of various polymeric binders can be used if desired in the inner imageable layer and such polymeric binders are generally present in the inner imageable layer in an amount of at least 10 weight %, and generally at least 60 weight % and up to and including 95 weight % of the total dry inner imageable layer weight.

As noted above, the inner imageable layer generally comprises an infrared radiation absorber (as described above) in an amount of generally at least 0.5 weight % and up to and including 30 weight % and typically at least 3 weight % and up to and including 25 weight %, based on the total dry weight of the inner imageable layer. The particular amount of a given compound to be used could be readily determined by one skilled in the art.

Formulations that are useful in inner imageable layers of positive-working multi-layer lithographic printing plate precursors are described, for example, in U.S. Pat. No. 6,294,311 (Shimazu et al.), U.S. Pat. No. 6,352,812 (Shimazu et al.), U.S. Pat. No. 6,593,055 (Shimazu et al.), U.S. Pat. No. 6,352,811 (Patel et al.), U.S. Pat. No. 6,358,669 (Savariar-Hauck et al.), U.S. Pat. No. 6,528,228 (Savariar-Hauck et al.), U.S. Pat. No. 7,163,770 (Saraiya et al.), U.S. Pat. No. 7,163,777 (Ray et al.), U.S. Pat. No. 7,186,482 (Kitson et al.), U.S. Pat. No. 7,223,506 (noted above), U.S. Pat. No. 7,229,744 (Patel), U.S. Pat. No. 7,241,556 (Saraiya et al.), U.S. Pat. No. 7,247,418 (noted above), U.S. Pat. No. 7,291,440 (Ray et al.), U.S. Pat. No. 7,300,726 (Patel et al.), and U.S. Pat. No. 7,338,745 (Ray et al.), U.S. Patent Application Publications 2004/0067432 Al (Kitson et al.) and 2005/0037280 (Loccufier et al.), all of which are incorporated herein by reference. Further details of useful inner layer formulations are provided in Invention Examples described below.

For example, the inner imageable layer can comprise at least one polymeric binder that has an acid number of at least 40 mg KOH/g of polymeric binder and that comprises recurring units derived from one or more N-alkoxymethyl (alkyl)acrylamides or alkoxymethyl (alkyl)acrylates, and optionally recurring units having pendant 1H-tetrazole groups or recurring units having pendant cyano. More details of such useful polymeric binder are provided in U.S. Patent Application Publication 2011/009766 (Savariar-Hauck et al.) that is incorporated herein by reference.

The outermost imageable layer of the lithographic printing plate precursor is disposed over the inner imageable layer and in most embodiments there are no intermediate layers between the inner imageable layer and the outermost imageable layer. The outermost imageable layer in a multi-layer precursor has a composition (components and amounts) like the outermost imageable layer described above for the single-layer precursor, so that information is not repeated here.

In many embodiments, the outermost imageable layer is disposed directly on the inner imageable layer that is disposed directly on the substrate.

The dry coating the inner imageable layer is generally at least 0.5 g/m² and up to and including 3.5 g/m², and more typically at least 0.8 g/m² and up to and including 2 g/m².

In some embodiments, the outermost imageable layer is substantially free of infrared radiation absorbers, meaning that none of these compounds are purposely incorporated therein and insubstantial amounts diffuse into it from other layers. However, in other embodiments, the infrared radiation absorbing compound can be in both the outermost imageable layer and the inner imageable layer, as described for example in EP 1,439,058A2 (Watanabe et al.) and EP 1,738,901A1 (Lingier et al.), incorporated herein by reference, or in an intermediate layer as known in the art.

The outermost imageable layer can also include colorants as described for example in U.S. Pat. No. 6,294,311 (noted above) including triarylmethane dyes such as ethyl violet, crystal violet, malachite green, brilliant green, Victoria blue B, Victoria blue R, and Victoria pure blue BO, in amounts that are known in the art. These compounds can act as contrast dyes that distinguish the non-exposed regions from the exposed regions in the developed lithographic printing plate precursor. The outermost imageable layer can optionally also include contrast dyes, printout dyes, coating surfactants, dispersing aids, humectants, biocides, viscosity builders, drying agents, defoamers, preservatives, and antioxidants in amounts that are known in the art.

The multi-layer lithographic printing plate precursors can be prepared by sequentially applying an inner imageable layer formulation over the surface of the substrate, and then applying an outermost imageable layer formulation over the inner imageable layer using conventional coating or lamination methods. It is important to avoid intermixing of the inner imageable layer and outermost imageable layer formulations.

The inner imageable layer and outermost imageable layer can be applied by dispersing or dissolving the desired ingredients in a suitable coating solvent(s), and the resulting formulations are sequentially applied to the substrate using suitable equipment and procedures, such as spin coating, knife coating, gravure coating, die coating, slot coating, bar coating, wire rod coating, roller coating, or extrusion hopper coating. The formulations can also be applied by spraying them onto the substrate.

The selection of solvents used to coat the imageable layers depends upon the nature of the polymeric binders and other components used in the respective formulations. To prevent the separate formulations from mixing or the inner imageable layer from dissolving when the outermost imageable layer formulation is applied, the outermost imageable layer formulation should be coated from a solvent in which the polymeric binder(s) of the inner imageable layer are insoluble.

Generally, the inner imageable layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane. Particular solvent mixtures are shown in the Examples below.

The outermost imageable layer formulation can be coated out of solvents or solvent mixtures that do not dissolve the inner imageable layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof. Particular solvent mixtures are shown in the Examples below.

After drying the applied layer formulations, the lithographic printing plate precursors can be further “conditioned” with a heat treatment for at least 40 and up to and including 90° C. for at least 4 hours (for example, at least 20 hours) under conditions that inhibit the removal of moisture from the dried layers. For example, the heat treatment is carried out for at least 50° C. and up to and including 70° C. for up to 24 hours or more. During the heat treatment, the lithographic printing plate precursors are wrapped or encased in a water-impermeable sheet material to represent an effective barrier to moisture removal from the precursors, or the heat treatment of the precursors is carried out in an environment in which relative humidity is controlled to at least 25%. In addition, the water-impermeable sheet material can be sealed around the edges of the precursors, with the water-impermeable sheet material being a polymeric film or metal foil that is sealed around the edges of the precursors.

In some embodiments, this heat treatment can be carried out with a stack comprising at least 100 of the same lithographic printing plate precursors, or when the precursor is in the form of a coil or web. When conditioned in a stack, the individual precursors can be separated by suitable interleaving papers. The interleaving papers can be kept between the imageable elements after conditioning during packing, shipping, and use by the customer.

### Imaging Conditions

During use, the lithographic printing plate precursor is exposed to a suitable source of exposing radiation depending upon the infrared radiation absorber present in an appropriate layer to provide specific sensitivity that is at a wavelength of at least 700 nm and up to and including 1500 nm. In some embodiments, imagewise exposure is carried out using radiation the range of at least 700 nm and up to and including 1400 nm.

For example, imaging can be carried out using imaging or exposing radiation from an infrared radiation-generating laser (or array of such lasers). Imaging also can be carried out using imaging radiation at multiple wavelengths at the same time if desired. The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen USA, Chicago, Ill.) that operates at a wavelength of 810 nm.

Imaging with infrared radiation can be carried out generally at imaging energies of at least 30 mJ/cm² and up to and including 1000 mJ/cm² and typically at least 50 mJ/cm² and up to and including 500 mJ/cm² depending upon the sensitivity of the imageable layer(s). With these platesetters, any imaging parameters such as the “surface depth” parameter of a Magnus 800 platesetter (Eastman Kodak Company) or the “focus” parameter of a PlateRite 4300 platesetter (Dainippon Screen Company), are decided by observing the difference in contrast between exposed regions and non-exposed regions in a stepwise imaging process. By using such as stepwise imaged lithographic printing plate precursor, a shortened printing run is possible and the obtained prints are also useful for determining such imaging parameters.

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. 5,488,025 (Martin et al.). Thermal print heads are commercially available (for example, a Fujitsu Thermal Head FTP-040 MCS001 and TDK Thermal Head F415 HH7-1089).

### Development and Printing

After imaging, the imaged lithographic printing plate precursors can be processed “off-press” using a suitable alkali solution or processing solution described herein. Such processing is carried out with imaged positive-working lithographic printing plate precursors of this invention for a time sufficient to remove the exposed regions of the imaged imageable layer(s) to reveal the hydrophilic surface of the substrate, but not long enough to remove significant amounts of the non-exposed regions of those layer(s). The revealed hydrophilic substrate surface repels inks while the non-exposed regions accept ink. Thus, the exposed regions to be removed are “soluble” or “removable” in the alkali solution or processing solution because they are removed, dissolved, or dispersed within it more readily than the non-exposed regions that are to remain. The term “soluble” also means “dispersible”.

Development off-press can be accomplished using what is known as “manual” development, “dip” development, or processing with an automatic development apparatus (processor). In the case of “manual” development, development is conducted by rubbing the imaged precursor with a sponge or cotton pad sufficiently impregnated with a suitable processing solution and followed by rinsing with water. “Dip” development involves dipping the imaged precursor in a tank or tray containing the appropriate processing solution for at least 10 and up to and including 60 seconds (especially at least 20 seconds and up to and including 40 seconds) under agitation, followed by rinsing with water with or without rubbing with a sponge or cotton pad. The use of automatic development apparatus is well known and generally includes pumping a processing solution or developer into a developing tank or ejecting it from spray nozzles. The imaged precursor is contacted with the developer in an appropriate manner The apparatus can also include a suitable rubbing mechanism (for example a brush or roller) and a suitable number of conveyance rollers. Some developing apparatus include laser exposure means and the apparatus is divided into an imaging section and a developing section.

The processing solution (or developer) can be applied to the imaged precursor by rubbing, spraying, jetting, dipping, immersing, slot die coating (for example see FIGS. 1 and 2 of U.S. Pat. No. 6,478,483 of Maruyama et al.) or reverse roll coating (as described in FIG. 4 of U.S. Pat. No. 5,887,214 of Kurui et al.), or by wiping the outermost imageable layer with the processing solution or contacting it with a roller, impregnated pad, or applicator. For example, the imaged precursor can be brushed with the processing solution, or it can be poured onto or applied by spraying the imaged surface with sufficient force to remove the non-exposed regions using a spray nozzle system as described for example in [0124] of EP 1,788,431A2 (noted above) and U.S. Pat. No. 6,992,688 (Shimazu et al.). As noted above, the imaged precursor can be immersed in the processing solution and rubbed by hand or with an apparatus. To assist in the removal of the back side coating, a brush roller or other mechanical component can be placed in contact with the back side coating during processing.

The processing solution can also be applied in a processing unit (or station) in a suitable apparatus that has at least one roller for rubbing or brushing the imaged precursor while the processing solution is applied. Residual processing solution can be removed (for example, using a squeegee or nip rollers) or left on the resulting lithographic printing plate without any rinsing step. Excess processing solution can be collected in a tank and used several times, and replenished if necessary from a reservoir. The processing solution replenisher can be of the same concentration as that used in processing, or be provided in concentrated form and diluted with water at an appropriate time.

Both aqueous alkaline developers and organic solvent-containing developers or processing solutions can be used. Some useful developer solutions are described for example, in U.S. Pat. No. 7,507,526 (Miller et al.) and U.S. Pat. No. 7,316,894 (Miller et al.) that are incorporated herein by reference. Developer solutions commonly include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates). Other useful developers contain no silicates and metasilicates.

Useful alkaline aqueous developer solutions include 3000 Developer, 9000 Developer, GOLDSTAR Developer, GREENSTAR Developer, ThermalPro Developer, PROTHERM Developer, MX1813 Developer, and MX1710 Developer (all available from Eastman Kodak Company). These compositions also generally include surfactants, chelating agents (such as salts of ethylenediaminetetraacetic acid), and alkaline components (such as inorganic metasilicates, organic metasilicates, hydroxides, and bicarbonates).

Organic solvent-containing developers are generally single-phase processing solutions of one or more organic solvents that are miscible with water. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of at least 0.5 weight % and up to and including 15% based on total developer weight. The organic solvent-containing developers can be neutral, alkaline, or slightly acidic in pH, and typically, they are alkaline in pH. Representative organic solvent-containing developers include ND-1 Developer, Developer 980, Developer 1080, 2 in 1 Developer, 955 Developer, D29 Developer (described below), and 956 Developer (all available from Eastman Kodak Company).

In some particularly useful embodiments of the method of this invention, the alkaline processing solution used for development has a pH of 12 or less, and that can be as low as 7. Typically, the pH is at least 8 and up to and including 12 or at least 8.5 and up to and including 11.5. This processing solution can also include at least 0.001 weight % and up to and including 1 weight % of a water-soluble or water-dispersible, non-IR-sensitive compound that has a heterocyclic moiety with a quaternary nitrogen in the 1-position of the heterocyclic ring. This compound also has one or more electron donating substituents attached to the heterocyclic ring, at least one of which electron donating substituents is attached in the 2-position. The amount of these compounds can be at least 0.1 weight % and up to and including 0.8 weight %. These compounds are sometimes identified herein as “additives” for the processing solution.

More specifically, the water-soluble or water-dispersible compounds have a dialkylaminophenyl or 3-indolyl group in the 2-position of the heterocyclic ring. Examples of such compounds include but are not limited to, Thioflavine T, Astrazon Orange G, and Basic Violet 16.

In addition, the processing solution can further comprise one or more of the following: anionic or nonionic surfactants, alkanolamines, organic solvents, organic phosphonic acids or polycarboxylic acids or salts thereof that are different from the anionic surfactant, and hydrophilic film-forming polymers.

For example, the processing solution can comprise at least 0.01 weight % of an alkanolamine (such as diethanolamine, triethanolamine, and monoethanolamine, or mixtures thereof), an organic phosphonic acid or polycarboxylic acid or salt thereof that is different from the anionic surfactant, or a hydrophilic film-forming polymer.

In addition, the processing solution can also comprise up to and including 8 weight % (based on total processing solution weight) of one or more organic solvents (described below). Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol.

Such processing solutions are generally free of silicates and metasilicates, meaning that none of these compounds is intentionally added to the processing solution. These silicate-free processing solutions can also be free of alkaline hydroxides.

In some embodiments, the processing solution has a pH of at least 8.5 and up to and including 11.5, and comprises at least 0.1 weight % and up to and including 0.8 weight % of one or more of Thioflavine T, Astrazon Orange G, and Basic Violet 16, and the processing solution is essentially free of silicates and metasilicates, and further comprises from at least 0.1 weight % and up to and including 5 weight % of an alkanolamine, organic phosphonic acid or polycarboxylic acid or salt thereof that is different from an anionic surfactant, or hydrophilic film-forming polymer, or mixtures thereof.

The processing solution can further include one or more surfactants that can act as “coating-attack suppressing agents” that are developer-soluble compounds that suppress developer attack of the outer layer in addition to the additives used according to this invention. “Developer-soluble” means that enough of the agent(s) will dissolve in the processing solution to suppress attack by the processing solution. Typically, the coating-attack suppressing agents are developer-soluble polyethoxylated, polypropoxylated, or polybutoxylated compounds that include recurring —(CH₂—CHRₐ—O—)— units in which Rₐ is hydrogen or a methyl or ethyl group. Representative compounds of this type include but are not limited to, polyglycols and polycondensation products having the noted recurring units. Examples of such compounds and representative sources, tradenames, or methods of preparing are described for example in U.S. Pat. No. 6,649,324 (Fiebag et al.).

Some of the processing solutions useful for the present invention can be formulated by taking a commercial organic solvent-containing alkaline developer and adding one or more non-IR sensitive compounds described above in suitable amounts. Developers that can be used in this manner include but are not limited to, ND-1 Developer, 955 Developer, 956 Developer, 989 Developer, Developer 980, and 956 Developer (available from Eastman Kodak Company), HDN-1 Developer and LP-DS Developer (available from Fuji Photo), and EN 232 Developer and PL10 Developer (available from Agfa). Some of these commercial developers include up to 20 weight % of one or more organic solvents such as phenoxy ethanol as others described above, as well as organic amines such as alkanolamines.

Other useful processing solutions of this invention can be prepared by mixing an “additive” as described above in silicate-free carbonate processing solutions as described for example in U.S. Patent Application Publication 2009-0197052 (Levanon et al.) that is incorporated herein by reference. Similarly, the “additive” can be mixed with carbonate processing solutions containing organic solvents, organic amines, anionic surfactants, or combinations thereof, as described for example in U.S. Patent Application Publications 2009-0291387 (Levanon et al.) and 2010-0047723 (Levanon et al.), both of which are incorporated herein by reference. Useful organic amines include those whose conjugated acids have a pKa greater than 9 and a boiling point greater than 150° C. Such organic amines can be present in an amount of at least 0.03 N or from 0.03 to 1.5 N, and include ethanol amine, 4-aminopyridine, 1,5-diaminopentane, 4-(2-aminoethyl)phenol, 1-ephedrine, 2-(ethylamino)ethanol, 3-amino-l-propanol, and 2-(2-aminoethylamino)ethanol. Further details are provided in the noted US '723 publication.

In some embodiments, the processing solution consists essentially of a carbonate, organic solvent, and the water-soluble or water-dispersible, non-IR-sensitive compound that has a heterocyclic moiety with a quaternary nitrogen in the 1-position of the heterocyclic ring. Thus, such solutions contain no other compounds that have a meaningful effect on development.

Following off-press development, the resulting lithographic printing plate can be postbaked with or without blanket or floodwise exposure to UV or visible radiation. Alternatively, a blanket UV or visible radiation exposure can be carried out, without a postbake operation.

Printing can be carried out by putting the imaged and developed lithographic printing plate on a suitable printing press. The lithographic printing plate is generally secured in the printing plate using suitable clamps or other holding devices. Once the lithographic printing plate is secured in the printing press, printing is carried out by applying a lithographic printing ink and fountain solution to the printing surface of the lithographic printing plate. The fountain solution is taken up by the surface of the hydrophilic substrate revealed by the imaging and processing steps, and the ink is taken up by the remaining regions of the outermost imageable layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material (for example, sheets of paper). The lithographic printing plates can be cleaned between impressions, if desired, using conventional cleaning means.

The present invention provides at least the following embodiments and combinations thereof, but other combinations of features are considered to be within the present invention as a skilled artisan would appreciate from the teaching of this disclosure:

1. A positive-working lithographic printing plate precursor that comprises:

a substrate,

an outermost imageable layer that is disposed over the substrate, and that comprises a combination of first and second alkali solution-soluble or -dispersible resins,

the positive-working lithographic printing plate precursor further comprising an infrared radiation absorber in the outermost imageable layer or in a different layer underneath the outermost imageable layer,

wherein the first alkali solution-soluble or -dispersible resin is a acid-functionalized novolak or acid-functionalized resole resin, and

wherein the second alkali solution-soluble or -dispersible resin is a polyurethane or polyurethane urea comprising a polysiloxane unit segment in the polyurethane or polyurethane urea backbone or side chain.

2. The precursor of embodiment 1 wherein:

the second alkali solution-soluble or -dispersible resin is a polyurethane or polyurethane urea that is derived from:
(i) reacting at least one polyisocyanate with a compound comprising two or more functional groups selected from the group consisting of hydroxyl and amino groups having at least one active hydrogen atom attached to the amino nitrogen atom, wherein the polyisocyanate is functionalized with a polysiloxane segment, either in its main chain or a side chain, or
(ii) reacting at least one polyisocyanate with a compound comprising two or more functional groups selected from the group consisting of hydroxyl and amino groups having at least one active hydrogen atom attached to the amino nitrogen atom, wherein the compound also comprises polysiloxane segments either in its main chain or a side chain.

3. The precursor of embodiment 2 wherein the compound in (ii) is a diol that has a polysiloxane segment in its backbone or a side chain and is a hydroxy-modified di-oligano siloxane having both terminal groups represented by the following structure:

—(CₖH₂ₖ)ₚ—(OCₘH₂ₘ)_{q}—(OCₙH₂ₙ)ᵣ—(C₆H₄)ₛ—OH

wherein k, m, and n independently represent integers of from 1 to and including 3,

p represents an integer of 1 or more,

q represents 0 or an integer of from 1 to and including 100,

r is 0 or an integer of from 1 to and including 100, and

s represents 0 or an integer of from 1 to and including 3.

4. The precursor of embodiment 2 wherein the compound in (ii) is a diol that has a polysiloxane segment in its backbone or a side chain, which polysiloxane segment is a diol-modified diorganopolysiloxane that is represented by the following structure:

(R¹)₃SiO—[(R¹)₂SiO]ₜ—Si(R¹)₂R²

wherein the multiple R¹ groups independently represent a substituted or unsubstituted alkyl group having 1 to carbon atoms or a substituted or unsubstituted aryl group having 6 to 20 total carbon atoms including the carbon atoms in the aromatic ring,

R² represents the following structure:

—(CₖH₂ₖ)ᵤ—(OCₘH₂ₘ)ᵥ—(OCₙH₂ₙ)_{w}—(C₆H₄)ₓ—CR¹(R³)₂

wherein k, m, and n independently represent integers of from 1 to and including 3,

u represents an integer or 1 or more,

v represents 0 or an integer of from 1 to and including 100,

w represents 0 or an integer of from 1 to and including 100, and

x represents 0 or an integer of from 1 to and including 3,

R³ represents —(C_{y}H_{2y})_{z}OH wherein y represents an integer of from 1 to and including 3 and z represents an integer of from 1 to and including 100, and

t represents an integer of from 1 to and including 10,000.

5. The precursor of any of embodiments 1 to 4 wherein the first alkali solution-soluble or -dispersible resin is present in the outermost imageable layer in an amount of at least 10 weight % and up to and including 90 weight % based on the outermost imageable layer total dry weight.

6. The precursor of any of embodiments 1 to 5 wherein second alkali solution-soluble or -dispersible resin is present in the outermost imageable layer in an amount of at least 5 weight % and up to and including 75 weight % based on the outermost imageable layer total dry weight.

7. The precursor of any of embodiments 1 to 6 wherein the weight ratio of the first alkali solution-soluble or -dispersible resin to the second alkali solution-soluble or -dispersible resin is from 0.2:1 and to and including 5:1.

8. The precursor of any of embodiments 1 to 7 wherein the first alkali solution-soluble or -dispersible resin is a carboxy-functionalized novolak or a carboxy-functionalized resole.

9. The precursor of any of embodiments 1 to 8 that further comprises an inner imageable layer disposed over the substrate and the outermost imageable layer is disposed over the inner imageable layer.

10. The precursor of embodiment 9 wherein the infrared radiation absorber is located only in the inner imageable layer.

11. The precursor of embodiment 9 or 10 wherein the inner imageable layer comprises at least one polymeric binder that has an acid number of at least 40 mg KOH/g of polymeric binder and comprises recurring units derived from one or more N-alkoxymethyl (alkyl)acrylamides or alkoxymethyl (alkyl)acrylates, and optionally recurring units having pendant 1H-tetrazole groups or recurring units having pendant cyano.

12. The precursor of any of embodiments 1 to 11 wherein the outermost imageable layer further comprises a developability enhancing composition.

13. The precursor of any of embodiments 1 to 12 further comprising an inner imageable layer disposed over the substrate and under the outermost imageable layer, and wherein the substrate is an aluminum-containing substrate.

14. The precursor of any of embodiments 9 to 13 wherein the outermost imageable layer is disposed directly on an inner imageable layer that is disposed directly on the substrate.

15. A method for forming a lithographic printing plate, comprising:

imagewise exposing the positive-working lithographic printing plate precursor of any of embodiments 1 to 13 with infrared radiation to form an imaged precursor comprising exposed regions and non-exposed regions in the outermost imageable layer, and

processing the imaged precursor to remove the exposed regions of the outermost imageable layer.

16. The method of embodiment 15 comprising processing the imaged precursor using an alkaline processing solution having a pH of at least 7 and up to and including 12.

17. The method of embodiment 15 or 16 comprising processing the imaged precursor using a processing solution comprising at least 0.001 weight % and up to and including 1 weight % of a water-soluble or water-dispersible, non-IR-sensitive compound that has a heterocyclic moiety with a quaternary nitrogen in the 1-position of the heterocyclic ring, and that has one or more electron donating substituents attached to the heterocyclic ring, at least one of which electron donating substituents is attached in the 2-position.

18 The method of any of embodiments 15 to 17 comprising processing the imaged precursor using a silicate-free processing solution.

The following Examples are provided to illustrate the practice of this invention and are not meant to be limiting in any manner.

The following materials were used in the examples:

Ethyl violet is identified as C.I. 42600 (CAS 2390-59-2, λmax=596 nm) and has a formula of p-(CH₃CH₂)₂NC₆H₄)₃C+ Cl⁻.

IR Dye A (KAN165493) is represented by the following formula and can be obtained from Eastman Kodak Company (Rochester, N.Y.).

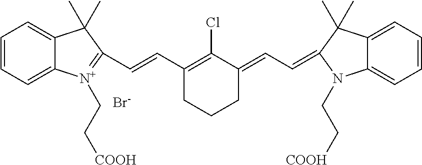 [SMILES: CC1(C)C(/C=C/C2=C(Cl)C(=C/C=C3/N(CCC(=O)O)c4ccccc4C3(C)C)/CCC2)=[N+](CCC(=O)O)c2ccccc21 ; [Br-]]

DEK represents diethyl ketone.

PMA represents 1-methoxy-2-propyl acetate.

BLO represents y-butyrolactone.

Byk® 307 is a polyethoxylated dimethylpolysiloxane copolymer that is available from Byk Chemie (Wallingford, Conn.).

D11 is ethanaminium, N-[4-[[4-(diethylamino)phenyl][4-(ethylamino)-1-naphthalenyl]methylene]-2,5-cyclohexadien-1-ylidene]-N-ethyl-, salt with 5-benzoyl-4-hydroxy-2-methoxybenzenesulfonic acid (1:1) as supplied by PCAS (Longjumeau, France), having the following structure:

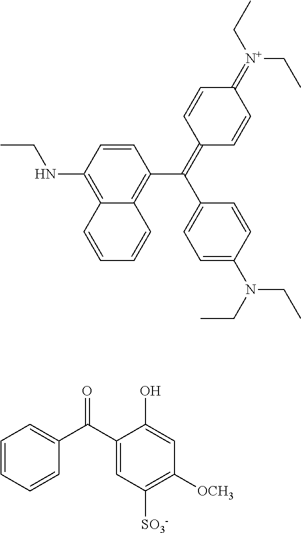

Co1030 is a nanoparticle dispersion from Evoniks (Germany). Polymer A is a polymer derived by polymerization of 5-aminotetrazole methacrylamide, methacrylic acid, N-phenyl maleimide, methacrylamide, acrylonitrile, and N-methoxymethyl methacrylamide 19.0/6.4/17.2/8.5/42.3/7.2 monomer weight % and had an acid value of 104 meq KOH/g.

Polymer B was an acidic novolak based on SPN562 (phenolic groups etherified with chloro acetic acid); theoretical AN=70, Mw=5600. SPN562 is a 44 weight % solution of m-cresol novolak from AZ Chemicals (Germany). This is a first water-insoluble, alkali solution-soluble or -dispersible resin useful in the practice of this invention.

The polyurethane Resins 1-5 identified in the following TABLE I were made by the synthetic method that follows for Resin 2:

Synthesis of Resin 2:

In a 2-liter reaction flask equipped with a thermometer, condenser, stirrer, and nitrogen inlet, was placed 311 g of dimethylacetamide. 68.4 g of dimethylolpropionic acid, 53.4 g of bis[4-(2-hydroxyethoxy)phenyl]sulfone, 47.5 g of 1,6-hexandiol, and 22.6 g of KF-6001 were added and the mixture heated to 90° C. under a Nitrogen atmosphere. Then, 0.44 g of dibutyltin dilaurate was added to the mixture. A pre-mixture of 207.4 g of dimethylacetamide and 255.4 g of 4,4′-diphenylmethane diisocyanate was added slowly over 1 hour while keeping the temperature at 90° C. The reaction was continued for 3 hours at the end of which 10 ml of methanol was added. The reaction mixture was cooled down and the solution precipitated in 5 liters of water and stirred for 3 hours. The precipitate was filtered and washed with water. The resulting polymer was dried at 40° C. for 48 hours.

Substrate A was a 0.3 mm gauge aluminum sheet that had been electrochemically grained, anodized, and subjected to treatment with poly(vinyl phosphonic acid).

Solvent Mixture A was a mixture of MEK:PMA:BLO:H₂O:Dioxalane, 45/20/10/10/15 weight ratio.

Solvent Mixture B was a mixture of DEK and PMA at 92:8 weight ratio.

Developer T212 developer (pH=10.5) comprises diethanolamine, polyethylene oxide, surfactants, and 0.02 weight % of Astrazon Orange G (can be prepared by mixing commercially available 980 Developer with the Astrazon Orange G).

The polyurethane resins identified in the following TABLE I were made by well known polymerization methods.

TABLE I

| | Outermost Imageable Layer | | | | |
|---|---|---|---|---|---|
| | Resins (weight %) | | | | |
| | 1 | 2 | 3 | 4 | 5 |
| Dimethylolpropionic acid | 14.8% | 15.3% | 15.2% | 15.2% | 15.3% |
| Bis[4-(2- | 11.2% | 11.9% | 11.4% | 10.2% | 11.7% |
| hydroxyethoxy)phenyl]- | | | | | |
| sulfone | | | | | |
| KF-6001 Silicon carbinol | 0 | 5.1% | 9.7% | 20.7% | 6.9% |
| dual end, available from | | | | | |
| Shin-Etsu (Japan) | | | | | |
| 1,6-Hexandiol | 10.2% | 10.6% | 9.0% | 5.0% | 0 |
| 4,4′-Diphenylmethane | 55.2% | 57.1% | 54.7% | 48.9% | 56.1% |
| Diisocyanate | | | | | |
| Polyfox ® PF6320 | 8.6% | 0 | 0 | 0 | 0 |
| (from OMNOVA) | | | | | |

Positive-working lithographic printing plate precursors were prepared as follows:

An inner imageable layer formulation was prepared by coating a lower layer formulation formed by dissolving 2.3 g of Polymer A, 0.15 g of IR Dye A, and 0.038 g of D11 in 37.5 g of Solvent Mixture A onto Substrate A and drying the coating at 135° C. for 45 seconds to provide a dry coating weight of 1.35 g/m².

Outermost imageable layer coating formulations 1-7 were prepared by dissolving the components (as weight in grams) as indicated in TABLE II below.

### INVENTION EXAMPLES 1-5 AND COMPARATIVE EXAMPLES 1-2

Lithographic printing plate precursors were prepared by providing top layers over bottom layer A as indicated below in TABLE II. Each top layer had a dry coating weight of about 0.58 g/m².

Each lithographic printing plate precursor was then conditioned for 1 day at 50° C. After 1 day at room temperature, evaluations were carried out as described below using a Mercury Mk6 processor containing the Developer T212 at 1500 mm/minute and 24° C.

TABLE II

| | Top layer Formulation: | | | | | | |
|---|---|---|---|---|---|---|---|
| | 1 | 2 | 3 | 4 | 5 | 6 | 7 |
| Polymer B | 1.37 | 1.37 | 1.37 | 1.37 | 1.44 | 1.44 | 1.37 |
| Resin 1 | 0.59 | | | | 0.62 | | |
| Resin 2 | | 0.59 | | | | | |
| Resin 3 | | | 0.59 | | | | |
| Resin 4 | | | | 0.59 | | 0.62 | |
| Resin 5 | | | | | | | 0.59 |
| Ethyl Violet | 0.0062 | 0.0062 | 0.0062 | 0.0062 | 0.0062 | 0.0062 | 0.0062 |
| Byk 302 | 0.0073 | 0.007 | 0.007 | 0.007 | 0.007 | 0.007 | 0.007 |
| CO1030 | 0.345 | 0.345 | 0.345 | 0.345 | 0 | 0 | 0.345 |
| Solvent | 32 | 32 | 32 | 32 | 32 | 32 | 32 |
| Mixture B | | | | | | | |

### Performance Evaluations:

The following evaluations were carried out for each of the lithographic printing plate precursors.

Developer Resistance:

To assess the resistance of the lithographic printing plate precursor to the developer, droplets of Developer T212 kept at 25° C. are placed on the unexposed precursor at 10 second intervals and then wiped off after a total of 120 seconds. The times at which the first visible attack of the precursor surface coating and complete dissolution were noted.

Drop Test:

To assess the speed of development, each lithographic printing plate precursor was imaged at 10 W/360 rpm (66 mJ/cm²). Droplets of Developer T212 kept at 25° C. are placed on the imaged precursor at 2 second intervals and rinsed off after 20 seconds. Each resulting lithographic printing plate was then inked, rinsed, and dried. The time required to obtain a clean background was noted for each precursor.

Photospeed and Ridges:

To assess the photospeed, each lithographic printing plate precursor was imaged with test patterns comprising solids and 8×8 checkerboard at 4 W to 16 W in steps of 1 W using a Creo Quantum 800 imagesetter (39 to 102 mJ/cm²). Each imaged precursor was developed in a Mercury Mk 6 Processor using Developer T212 at 25° C. and 1500 mm/min. Each resulting lithographic printing plate was then evaluated for clear point and image attack that are visible as ridges. The “clear point” refers to the lowest exposure energy (mJ/cm²) needed to render the substrate surface in the IR laser exposed regions as non-ink receptive after the exposed precursor is processed using Developer 212 under the stated conditions. The term “regular exposure” (mJ/cm²) refers to the exposure energy about 25% above the clear point.

Scratch Sensitivity:

Scratch sensitivity was assessed by placing individual metal weights of 300 g, 600 g, 900 g, 1200 g, and 1500 g on the outermost imageable layer surface of each precursor that was covered with an interleaf paper. The interleaf carrying the weight was clamped on to a bar and pulled at a constant speed over the precursor outermost surface. The precursors were subsequently processed in Developer T212 in the processor at 1500 mm/min and 25° C. Each precursor was assessed for scratches and given a relative figure using a scale of 0 to 4 where 4 indicates the highest level of scratches and 0 indicates no scratches.

The results of the various evaluations are provided below in TABLES III and IV.

TABLE III

| Examples Layer | Comparative | Invention | Invention | Invention | Comparative | Invention | Invention |
|---|---|---|---|---|---|---|---|
| Compositions | Example 1 | Example 1 | Example 2 | Example 3 | Example 2 | Example 4 | Example 5 |
| Outermost Imageable layer A | 1 | 2 | 3 | 4 | 5 | 6 | 7 |
| Formulation: | | | | | | | |
| Soak Test (visible attack/ | 40 sec/ | 40 sec/ | 40 sec/ | 40 sec/ | 40 sec/ | 40 sec/ | 30 sec/ |
| complete dissolution times) | 90 sec | 90 sec | 90 sec | 90 sec | 100 sec | 100 sec | 60 sec |
| Drop test (imaged) | 4 seconds | 4 seconds | 4 seconds | 4 seconds | 4 seconds | 4 seconds | 2 seconds |
| Image attack (ridges) | Very | Very slight | None | None | Very | Very slight | Strong |
| | slight | | | | slight | | |
| Clear point (mJ/cm²) | 73 | 73 | 73 | 66 | 73 | 66 | 46 |
| Regular Exposure (mJ/cm²) | 92 | 92 | 92 | 92 | 92 | 92 | 85 |
| 50% Dot at regular Exposure | 50.2 | 50.5 | 50.6 | 50.1 | 49.9 | 49.7 | 45.4 |
| (8 × 8 at 92 mJ/cm²) | | | | | | | |

The results shown in TABLE III indicate that no significant adverse changes in the lithographic printing plate precursors were observed with the use of the “second” alkali solution-soluble or -dispersible resin in the outermost imageable layer comprising siloxane units in its backbone.

TABLE IV

| Scratch Sensitivity | Comparative | Invention | Invention | Invention | Comparative | Invention | Invention |
|---|---|---|---|---|---|---|---|
| Tests | Example 1 | Example 1 | Example 2 | Example 3 | Example 2 | Example 4 | Example 5 |
| 300 g | 3 | 1 | 1 | 1 | 3 | 1 | 1 |
| 600 g | 4 | 2 | 1 | 1 | 4 | 1 | 1 |
| 900 g | 4 | 3 | 1 | 1 | 4 | 1 | 1 |
| 1200 g | 4 | 2 | 1 | 1 | 4 | 1 | 1 |
| 1500 g | 4 | 4 | 1 | 1 | 4 | 1 | 1 |
| Total | 19 | 12 | 5 | 5 | 19 | 5 | 5 |

The results shown in TABLE IV indicate that the scratch sensitivity of the positive-working lithographic printing plate precursors of this invention were significantly improved by substituting the polyurethane binder in the outermost imageable layer used in the Comparative Examples 1-2 with the polyurethane resins having siloxane units in polymer backbone according to the present invention.

The experimentation shown above is demonstrated only with two-layer positive-working lithographic printing plates, but the same results of improved scratch sensitivity are expected with single-layer positive-working lithographic printing plate precursors.

The invention has been described in detail with particular reference to certain preferred embodiments thereof, but it will be understood that variations and modifications can be effected within the spirit and scope of the invention.

1. A positive-working lithographic printing plate precursor that comprises:
a substrate,
an outermost imageable layer that is disposed over the substrate, and that comprises a combination of first and second alkali solution-soluble or -dispersible resins,
the positive-working lithographic printing plate precursor further comprising an infrared radiation absorber in the outermost imageable layer or in a different layer underneath the outermost imageable layer,
wherein the first alkali solution-soluble or -dispersible resin is a acid-functionalized novolak or acid-functionalized resole resin, and
wherein the second alkali solution-soluble or -dispersible resin is a polyurethane or polyurethane urea comprising a polysiloxane unit segment in the polyurethane or polyurethane urea backbone or side chain.

2. The precursor of claim 1 wherein:
the second alkali solution-soluble or -dispersible resin is a polyurethane or polyurethane urea that is derived from:
(i) reacting at least one polyisocyanate with a compound comprising two or more functional groups selected from the group consisting of hydroxyl and amino groups having at least one active hydrogen atom attached to the amino nitrogen atom, wherein the polyisocyanate is functionalized with a polysiloxane segment, either in its main chain or a side chain, or
(ii) reacting at least one polyisocyanate with a compound comprising two or more functional groups selected from the group consisting of hydroxyl and amino groups having at least one active hydrogen atom attached to the amino nitrogen atom, wherein the compound also comprises polysiloxane segments either in its main chain or a side chain.

3. The precursor of claim 2 wherein the compound in (ii) is a diol that has a polysiloxane segment in its backbone or a side chain and is a hydroxy-modified di-oligano siloxane having both terminal groups represented by the following structure:
—(CₖH₂ₖ)ₚ—(OCₘH₂ₘ)_{q}—(OCₙH₂ₙ)ᵣ—(C₆H₄)ₛ—OH
wherein k, m, and n independently represent integers of from 1 to and including 3,
p represents an integer of 1 or more,
q represents 0 or an integer of from 1 to and including 100,
r is 0 or an integer of from 1 to and including 100, and
s represents 0 or an integer of from 1 to and including 3.

4. The precursor of claim 2 wherein the compound in (ii) is a diol that has a polysiloxane segment in its backbone or a side chain, which polysiloxane segment is a diol-modified diorganopolysiloxane that is represented by the following structure:
(R¹)₃SiO—[(R¹)₂SiO]ₜ—Si(R¹)₂R²
wherein the multiple R¹ groups independently represent a substituted or unsubstituted alkyl group having 1 to carbon atoms or a substituted or unsubstituted aryl group having 6 to 20 total carbon atoms including the carbon atoms in the aromatic ring,
R² represents the following structure:
—(CₖH₂ₖ)ᵤ—(OCₘH₂ₘ)ᵥ—(OCₙH₂ₙ)_{w}—(C₆H₄)ₓ—CR¹(R³)₂
wherein k, m, and n independently represent integers of from 1 to and including 3,
u represents an integer or 1 or more,
v represents 0 or an integer of from 1 to and including 100,
w represents 0 or an integer of from 1 to and including 100, and
x represents 0 or an integer of from 1 to and including 3,
R³ represents —(C_{y}H_{2y})_{z}OH wherein y represents an integer of from 1 to and including 3 and z represents an integer of from 1 to and including 100, and
t represents an integer of from 1 to and including 10,000.

5. The precursor of claim 1 wherein the first alkali solution-soluble or -dispersible resin is present in the outermost imageable layer in an amount of at least 10 weight % and up to and including 90 weight % based on the outermost imageable layer total dry weight.

6. The precursor of claim 1 wherein second alkali solution-soluble or -dispersible resin is present in the outermost imageable layer in an amount of at least 5 weight % and up to and including 75 weight % based on the outermost imageable layer total dry weight.

7. The precursor of claim 1 wherein the weight ratio of the first alkali solution-soluble or -dispersible resin to the second alkali solution-soluble or -dispersible resin is from 0.2:1 and to and including 5:1.

8. The precursor of claim 1 wherein the first alkali solution-soluble or -dispersible resin is a carboxy-functionalized novolak or a carboxy-functionalized resole.

9. The precursor of claim 1 that further comprises an inner imageable layer disposed over the substrate and the outermost imageable layer is disposed over the inner imageable layer.

10. The precursor of claim 9 wherein the infrared radiation absorber is located only in the inner imageable layer.

11. The precursor of claim 9 wherein the inner imageable layer comprises at least one polymeric binder that has an acid number of at least 40 mg KOH/g of polymeric binder and comprises recurring units derived from one or more N-alkoxymethyl (alkyl)acrylamides or alkoxymethyl (alkyl)acrylates, and optionally recurring units having pendant 1H-tetrazole groups or recurring units having pendant cyano.

12. The precursor of claim 1 wherein the outermost imageable layer further comprises a developability enhancing composition.

13. The precursor of claim 1 further comprising an inner imageable layer disposed over the substrate and under the outermost imageable layer, and wherein:
the substrate is an aluminum-containing substrate,
the inner imageable layer comprises an infrared radiation absorber and at least one alkali solution-soluble or -dispersible polymeric binder that is different than the first and second alkali solution-soluble or -dispersible resins, and
the outermost imageable layer comprises a combination of a first alkali solution-soluble or -dispersible resin and a second alkali solution-soluble or -dispersible resin,
wherein:
(a) the second alkali solution-soluble or -dispersible resin is a polyurethane or polyurethane urea that is derived from:
(i) reacting at least one polyisocyanate with a compound comprising two or more functional groups selected from the group consisting of hydroxyl and amino groups having at least one active hydrogen atom attached to the amino nitrogen atom, wherein the polyisocyanate is functionalized with a polysiloxane segment, either in its main chain or a side chain, or
(ii) reacting at least one polyisocyanate with a compound comprising two or more functional groups selected from the group consisting of hydroxyl and amino groups having at least one active hydrogen atom attached to the amino nitrogen atom, wherein the compound also comprises polysiloxane segments either in its main chain or a side chain,
(b) the first alkali solution-soluble or -dispersible resin is present in the outermost imageable layer in an amount of at least 10 weight % and up to and including 90 weight % based on the outermost imageable layer total dry weight,
(c) the second alkali solution-soluble or -dispersible resin is present in the outermost imageable layer in an amount of at least 5 weight % and up to and including 75 weight % based on the outermost imageable layer total dry weight, and
(d) the weight ratio of the first alkali solution-soluble or -dispersible resin to the second alkali solution-soluble or -dispersible resin is from 0.2:1 to and including 5:1.

14. The precursor of claim 9 wherein the outermost imageable layer is disposed directly on an inner imageable layer that is disposed directly on the substrate.

15. A method for forming a lithographic printing plate, comprising:
imagewise exposing the positive-working lithographic printing plate precursor of claim 1 with infrared radiation to form an imaged precursor comprising exposed regions and non-exposed regions in the outermost imageable layer, and
processing the imaged precursor to remove the exposed regions of the outermost imageable layer.

16. The method of claim 15 comprising processing the imaged precursor using an alkaline processing solution having a pH of at least 7 and up to and including 12.

17. The method of claim 15 comprising processing the imaged precursor using a processing solution comprising at least 0.001 weight % and up to and including 1 weight % of a water-soluble or water-dispersible, non-IR-sensitive compound that has a heterocyclic moiety with a quaternary nitrogen in the 1-position of the heterocyclic ring, and that has one or more electron donating substituents attached to the heterocyclic ring, at least one of which electron donating substituents is attached in the 2-position.

18. The method of claim 15 comprising processing the imaged precursor using a silicate-free processing solution.

19. A method for forming a lithographic printing plate, comprising:
imagewise exposing the positive-working lithographic printing plate precursor of claim 14 with infrared radiation to form an imaged precursor comprising exposed regions and non-exposed regions in the outermost imageable layer, and
processing the imaged precursor to remove the exposed regions of the outermost imageable layer.

20. A lithographic printing plate prepared using the method of claim 15, the lithographic printing plate comprising an aluminum substrate having thereon an outermost imageable layer having non-exposed regions,
the non-exposed regions comprising a combination of first and second alkali solution-soluble or -dispersible resins,
wherein the first alkali solution-soluble or -dispersible resin is a acid-functionalized novolak or acid-functionalized resole resin, and
wherein the second alkali solution-soluble or -dispersible resin is a polyurethane or polyurethane urea comprising a polysiloxane unit segment in the polyurethane or polyurethane urea backbone or side chain,
the lithographic printing plate further comprising an infrared radiation absorber in the non-exposed regions of the outermost imageable layer or in a different layer underneath the non-exposed regions of the outermost imageable layer.
